(19) United States
(12) Patent Application Publication
(10) Pub. No.: US 2003/0031182 A1
(43) Pub. Date: Feb. 13, 2003

(54) Methods and apparatus for delivering multimedia communications services to multiple tenants in a building

(76) Inventors: John M. O'Neil, Litchfield, CT (US); Gary R. Carlson, Bristol, CT (US); Alan B. Katze, Oxford, CT (US); David H. Kreitner, Cheshire, CT (US); Saskia E. Zezima, Naugatuck, CT (US)

Correspondence Address: Gordon & Jacobson, P.C., 65 Woods End Road, Stamford, CT, 06905, US

(21) Appl. No.: 10/099,073

(22) Filed: Mar. 15, 2002

Related U.S. Application Data
(60) Provisional application No. 60/276,630, filed on Mar. 16, 2001.

(51) Int. Cl. H04J 3/14

(52) U.S. Cl. 370/395.1; 370/229

(57) ABSTRACT

The invention includes a service exchange platform, a service access unit, and a service provisioning system. The service exchange platform provides one or more trunk interfaces with public and private communications networks. The service access unit provides multimedia communications service including voice and data service to the tenant premises. The service provisioning system is a software platform for managing a network of service exchange platforms and service access units. Within the service exchange platform and the service access unit and/or in communications between them, a modified ETHERNET protocol is used. Specifically, the 48-bit MAC field in each ETHERNET packet is redefined to include a QOS indicator and ATM VPI/VCI type routing information. This enables rapid routing of packets throughout the system and maintenance of QOS for voice packets.

This application claims the benefit of provisional application serial No. 60/276,630 filed Mar. 16, 2001, the complete disclosure of which is incorporated by reference herein.

### BACKGROUND OF THE INVENTION

1. Field of the Invention

The invention relates to communications networks. More particularly, the invention relates to methods and apparatus for delivering multimedia communications services to multiple tenants in a building.

2. State of the Art

Recently there have been many changes in the way communications services are delivered to customers. Most businesses and many homes require multiline telephone service and high speed Internet access. Many companies are competing to provide all of a customer's communication needs in one efficient package. One new kind of service provider is the building local exchange company (BLEC) which may also serve as an Internet BPOP (building point of presence). BLECs contract with the owner/manager of a multi-tenant unit (MTU) to provide a full range of communication services for all of the tenants. Typical MTUs include office buildings which house many different businesses, hotels which offer in-room Internet access, college dormitories, etc. One of the challenges faced by BLECs is to provide the necessary cabling throughout the building for delivery of multiple communications services including voice telephony, Internet access, video delivery, etc. Another challenge faced by BLECs is to assure that the system they use is scalable so that as building tenants require additional bandwidth, the system can be expanded as easily as possible without the need for new cabling.

### SUMMARY OF THE INVENTION

It is therefore an object of the invention to provide methods and apparatus for delivering multimedia communications services to multiple tenants in a building.

It is also an object of the invention to provide methods and apparatus for delivering multimedia communications services to multiple tenants in a building which require minimum cabling.

It is another object of the invention to provide methods and apparatus for delivering multimedia communications services to multiple tenants in a building which are easily scalable.

In accord with these objects which will be discussed in detail below, the apparatus of the present invention includes three basic components: a service exchange platform, a service access unit, and a service provisioning system. The service exchange platform provides one or more trunk interfaces with public and private communications networks. The service access unit provides multimedia communications service including voice and data service to the tenant premises. The service provisioning system is a software platform for managing a network of service exchange platforms and service access units. According to the invention, each service access unit is coupled to a service exchange platform via an ETHERNET (or modified ETHERNET) connection.

According to the presently preferred embodiment, the service exchange platform is provided in two sizes. The smaller size supports up to twenty-four service access units and one trunk interface. The larger size supports up to one hundred twenty service access units and two trunk interfaces (one active and one backup. The trunk interfaces may be DS-3, OC-3, or Quad T1 IMA. Each service access unit supports a 10/100 Base-T ETHERNET link which can be coupled to a customer's hub or switch, up to eight subscriber line interfaces which essentially provide up to eight POTS lines or a single DSX-1 interface which can be coupled to a customer's PBX switch and provide up to twenty-four POTS lines.

According to one of the methods of the invention, the link between the service access units and the service exchange platform utilizes standard ETHERNET cabling, e.g. Category-5 or fiber. However, the ETHERNET protocol is modified to provide ATM-like routing and quality of service (QOS). According to this method of the invention, the 48-bit MAC field in each ETHERNET packet is redefined to include a QOS indicator and an ATM VPI/VCI routing information. According to this embodiment of the invention, all data (including digitized voice data) is packetized into ATM cells. The ATM cells are encapsulated into ETHERNET packets with the modified MAC field including the ATM VPI/VCI for the cell and a QOS indication. This enables rapid routing of packets throughout the system and maintenance of QOS for voice packets. Packets with a high QOS indication are given priority over packets with a low QOS indication. Where the invention interfaces with ATM equipment, ATM cells are ETHERNET packetized/depacketized without further processing. Where the invention interfaces with non-ATM equipment, data is extracted from/inserted into the ATM cell payload.

According to another method of the invention, the link between the service access units and the service exchange platform is a standard ETHERNET connection. However, within the service exchange platform, modified ETHERNET packets of the type described above are used to transfer data between controller/trunk card(s) and line card(s) over a PCI bus. Similarly, within the service access units, data between the ETHERNET network interface card and the local data and voice port(s) is transferred using the modified ETHERNET packets of the type described above.

Additional objects and advantages of the invention will become apparent to those skilled in the art upon reference to the detailed description taken in conjunction with the provided figures.

### BRIEF DESCRIPTION OF THE DRAWINGS

FIG. 1 is a high level schematic diagram of a system according to the invention including one service exchange platform coupled to seven service access units;

FIG. 2 is a diagram of the front of a controller card for the service exchange platform;

FIG. 3 is a diagram of the front of a controller card with a mezzanine trunk interface card installed;

FIG. 4 is a diagram of the rear of a line card for coupling the service exchange platform to up to eight service access units;

FIG. 5 is a schematic perspective view illustrating the rear of a service access unit according to the invention;

FIG. 6 is a schematic front and side view of modified ETHERNET line card for use in the service access point to couple it to the line card in the service exchange platform;

FIG. 7 is a schematic front and side view of a 4-port subscriber line interface card for use with the service access unit;

FIG. 8 is a schematic front and side view of a DSX-1 card for use with the service access unit; and

FIG. 9 is a simplified schematic diagram illustrating the second method of the invention.

### BRIEF DESCRIPTION OF THE APPENDICES

The enclosed CD-ROM appendix is incorporated herein by reference. The CD-ROM is in ISO 9660 Macintosh® format and includes the following Adobe® Acrobat® files:

| List of files | Size (Bytes) | Date of Creation |
|---|---|---|
| app-a.pdf | 1,001,170 | Mar. 14, 2002 |
| app-b.pdf | 923,278 | Mar. 14, 2002 |
| app-c.pdf | 79,591 | Mar. 14, 2002 |
| app-d.pdf | 199,307 | Mar. 14, 2002 |
| app-e.pdf | 18,733 | Mar. 14, 2002 |
| app-f.pdf | 47,888 | Mar. 14, 2002 |
| app-g.pdf | 7,208,576 | Mar. 14, 2002 |

These files represent Appendices A-G which are described in more detail as follows:

Appendix A is a document detailing the system architecture of the service exchange platform of the invention (43 pages);

Appendix B is a document detailing the architecture of the service access unit of the invention (8 pages);

Appendix C is a document illustrating various functions of the service access unit (10 pages);

Appenix D is a document detailing the architecture of the line cards which are used in the service exchange platform to couple to the service access units (15 pages);

Appendix E is a document briefly describing the functions of a controller card which is used in the service exchange platform (2 pages);

Appendix F is a document detailing the architecture of the software used by the controller card (14 pages); and

Appendix G is a document detailing the architecture of the service provisioning system of the invention (352 pages).

Appendices A-F are identical to the Appendices A-F filed in the above referenced provisional application. Appendix G is a more recent version of the previously filed Appendix G.

### DETAILED DESCRIPTION OF THE PREFERRED EMBODIMENTS

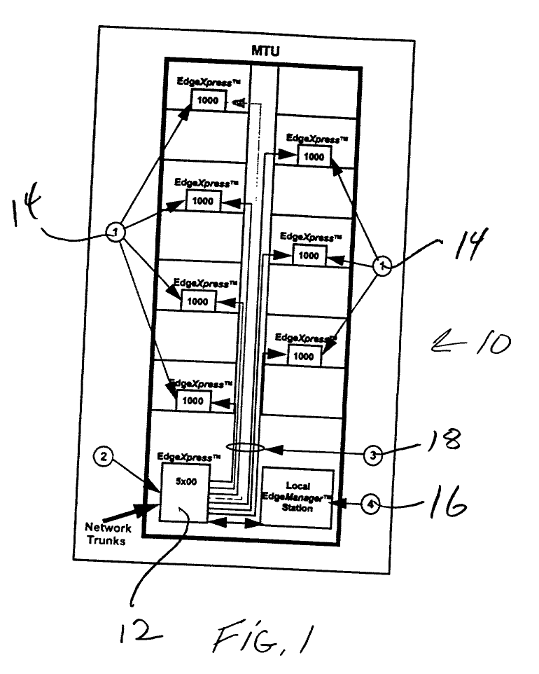

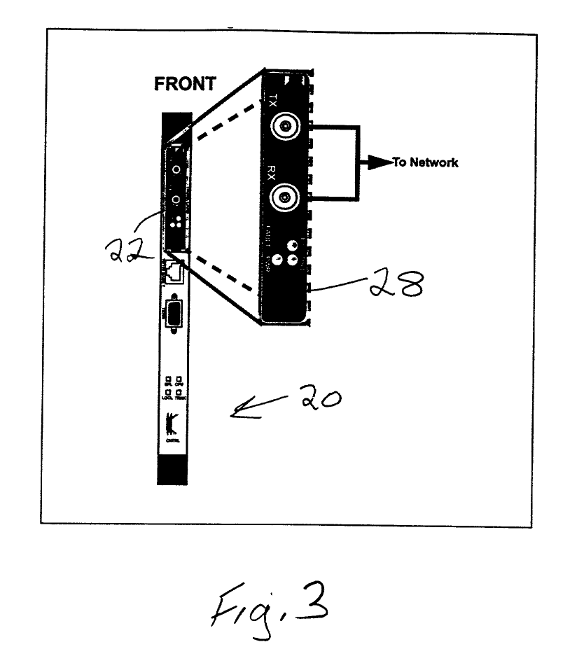

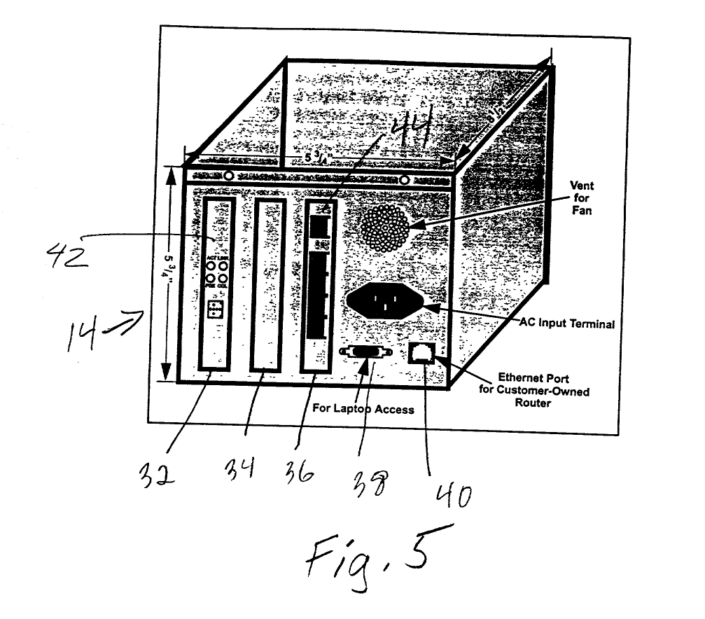

Referring now to FIG. 1, a system 10 according to the invention includes three basic components: a service exchange platform 12, a (plurality of) service access unit(s) 14, and a service provisioning system 16. As described in more detail below with reference to FIG. 3, the service exchange platform 12 provides one or more trunk interfaces with public and private communications networks. As described in more detail below with reference to FIGS. 5, 7, and 8, the service access unit 14 provides multimedia communications service including voice and data service to tenant premises. The service provisioning system 16 is a software platform for managing a network of service exchange platforms and service access units. Details about the service provisioning software are set out in Appendix G. According to the invention, each service access unit 14 is coupled to a service exchange platform 12 via a modified ETHERNET connection 18.

According to the presently preferred embodiment, the service exchange platform 12 is provided in two sizes. The smaller size supports up to twenty-four service access units and one trunk interface. The larger size supports up to one hundred twenty service access units and two trunk interfaces (one active and one backup. The trunk interfaces may be DS-3, OC-3, or Quad T1 IMA. The service exchange platform includes a PCI backplane which provides a plurality of slots for three different kinds of cards: a controller card, an optical ETHERNET line card, and a copper ETHERNET line card. The controller card accepts three different kinds of mezzanine cards for interfacing with a public and/or private communications networks. According to another embodiment of the invention, VDSL links are provided between the service access units and the service exchange platform and/or between the service exchange platform and the PSTN/ISP.

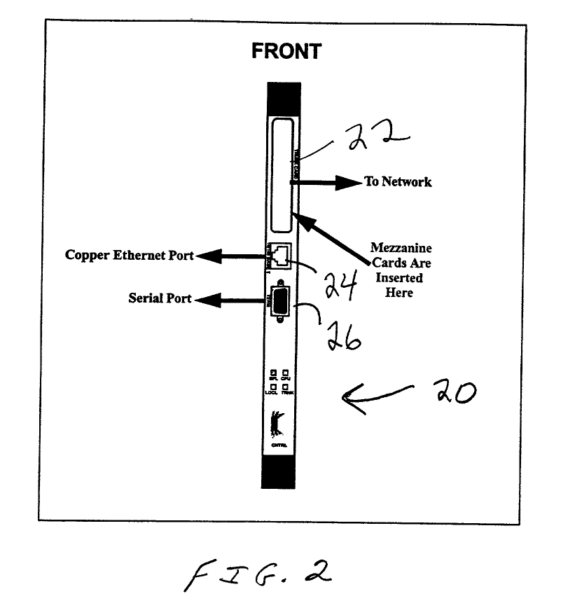

FIG. 2 illustrates a controller card 20 according to the invention. The controller card includes a mezzanine card slot 22, an ETHERNET port 24, and a serial port 26. The mezzanine card slot 22 is adapted to receive DS-3, OC-3, or Quad T1 IMA trunk interface card. The ETHERNET port 24 or the serial port 26 are used to couple to a PC running the service provisioning software.

FIG. 3 illustrates the controller card with a DS-3 interface card 28 in the mezzanine slot 22. As mentioned above and described in Appendix A, an OC-3, or Quad T1 IMA trunk interface card may be used in conjunction with the controller card in lieu of the DS-3 interface card 28.

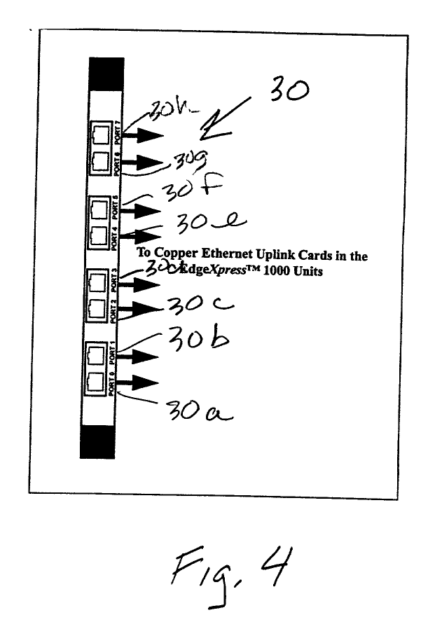

FIG. 4 illustrates a copper ETHERNET line card 30 which provides eight access ports 30a-30h. As mentioned above and as described in more detail in Appendix A, an optical ETHERNET line card is also provided for use with the service exchange platform.

Turning now to FIG. 5, each service access unit 14 includes three PCI card slots 32, 34, 36, a serial port 38, and a 10/100 Base-T ETHERNET link 40 which can be coupled to a customer's hub or switch. One of the slots is reserved for a link card 42 for linking the service access unit 14 with a service exchange platform (12 in FIG. 1). The other two slots are available for either subscriber line interface cards 44 or DSX-1 cards (46 in FIG. 8).

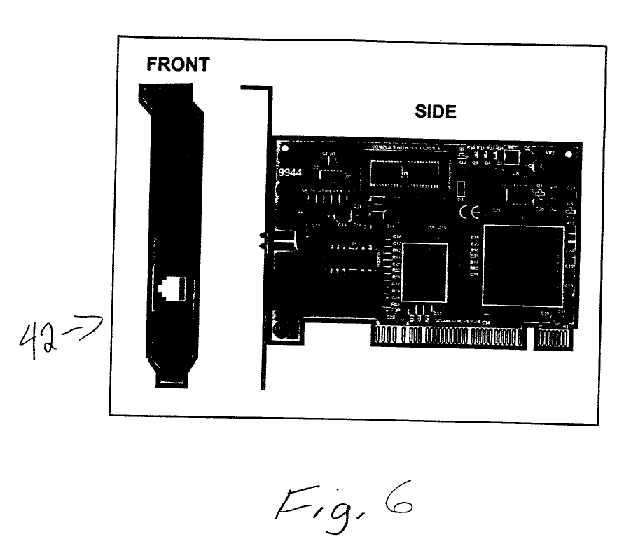

FIG. 6 illustrates a front and side view of a copper based 10/100 baseT PCI card 42. As mentioned above, the invention also provides a fiber based alternative card.

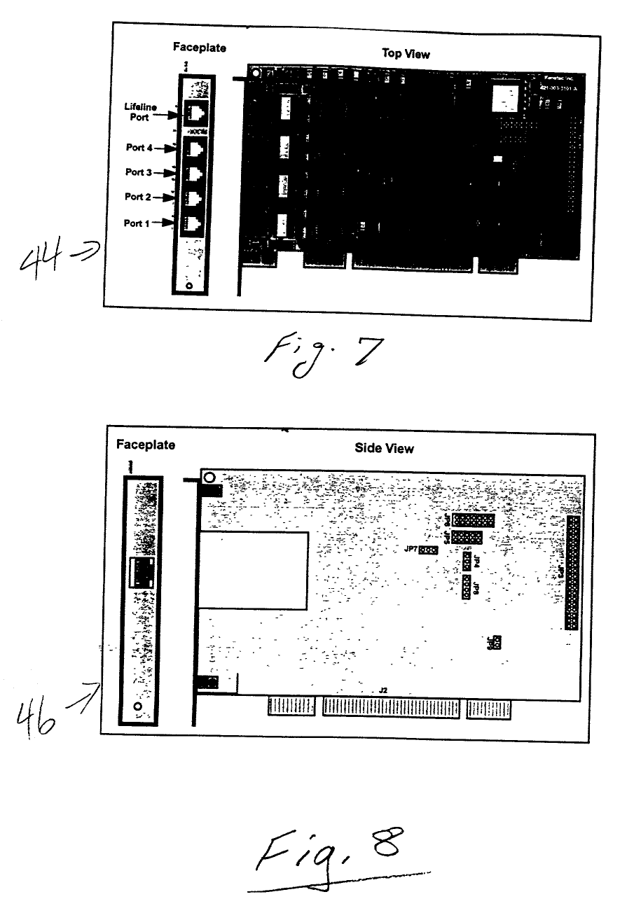

FIG. 7 illustrates a front and side view of a subscriber line interface card 44 according to the invention. The card includes five RJ-11 jacks. One RJ-11 jack is provided for coupling the card to a POTS lifeline. The other four RJ-11 jacks support either four or eight subscriber lines via the ETHERNET link to the service exchange platform. In the event of a power failure, all of the devices coupled to the card are coupled to the POTS lifeline as extensions.

FIG. 8 illustrates a front and side end view of a DSX-1 card 46 according to the invention. This card includes a single RJ-45 jack for coupling to a digital PBX and provides a 1.544 Mb/s fractional T-1 connection which can be divided into up to twenty-four channels of 64 Kb/s each.

According to the methods of the invention, the link between the service access units and the service exchange platform utilizes standard ETHERNET cabling, i.e. Category-5 or fiber. However, according to the invention, the ETHERNET protocol is modified to provide ATM-like routing and quality of service (QOS). In particular, the 48-bit MAC field in each ETHERNET packet is redefined to include a QOS indicator and ATM VPI/VCI routing information. According to the presently preferred embodiment of the invention, all data (including digitized voice data) is packetized into ATM cells, preferably using the AAL-2 standard. The ATM cells are then encapsulated into ETHERNET packets with the modified MAC field including the ATM VPI/VCI for the cell and a QOS indication. This enables rapid routing of packets throughout the system and maintenance of QOS for voice packets. Packets with a high QOS indication are given priority over packets with a low QOS indication. Details regarding the “pseudoMAC” according to the invention are provided in Appendix A.

In particular, a standard MAC address is 6 bytes long, and the definition of the “pseudoMAC” address is as follows:

| Byte 6 | | | | | Byte 1 |
|---|---|---|---|---|---|
| (MSB) | Byte 5 | Byte 4 | Byte 3 | Byte 2 | (LSB) |
| Unused | Unused | Unused | Unused | Channel | Type |

The Type byte indicates the type of data in the packet (0×01 for data, 0×02 for voice, 0×03 for management. The Channel byte is only used by the line card(s). When a packet is sent to a line card, it only requires the type byte of the pseudoMAC address. The line card provides both the type and channel to allow the Ethernet switch on the line card to send the packet to the correct port of the line card. The Type byte corresponds to a QOS indicator and the Channel byte corresponds to an ATM VPI/VCI routing field. According to the presently preferred embodiment, ATM VPI/VCI information is mapped to a “channel” which corresponds to a hardware address within the system.

Where the invention interfaces with ATM equipment, ATM cells are ETHERNET packetized/depacketized without further processing. Where the invention interfaces with non-ATM equipment, data is extracted from/inserted into the ATM cell payload.

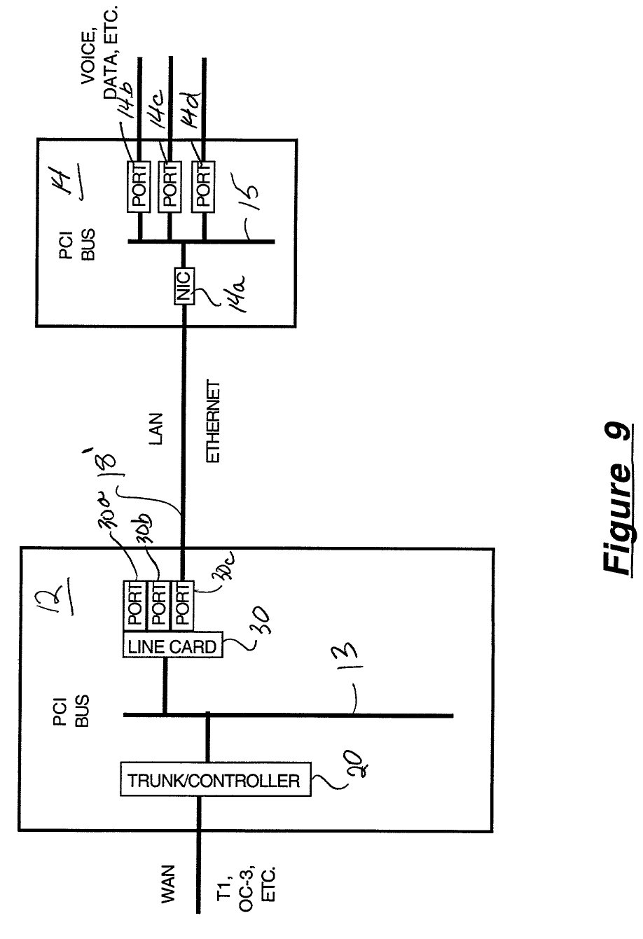

FIG. 9 illustrates how a second embodiment of the invention is implemented. According to the second method of the invention, the link between the service access units 14 and the service exchange platform 12 is a standard ETHERNET connection 18′. However, within the service exchange platform 12, modified ETHERNET packets of the type described above are used to transfer data between controller/trunk card(s) 20 and line card(s) 30 over a PCI bus 13. Similarly, within the service access units 14, data between the ETHERNET network interface card 14a and the local data and voice port(s) 14b, 14c, 14d, etc. is transferred using the modified ETHERNET packets of the type described above. Although the PCI bus is presently preferred, it will be appreciated that another bus with similar performance characteristics could be used. In addition, for purposes of claiming this aspect of the invention, the trunk/controller card 20 and the network interface card 14a may both be referred to as network interfaces or network interface devices. This is consistent because both devices interface with a network. The card 20 interfaces with a wide area network and the card 14a interfaces with a local area network.

Those skilled in the art will appreciate that the methods of the invention can be used individually or in conjunction with each other.

There have been described and illustrated herein methods and apparatus for delivering multimedia communications services to multiple tenants in a building. While particular embodiments of the invention have been described, it is not intended that the invention be limited thereto, as it is intended that the invention be as broad in scope as the art will allow and that the specification be read likewise.

1. A system for delivering multimedia communications services to multiple tenants in a building, said system comprising:
a) a service exchange platform coupled to one or more private and/or public communications networks; and
b) a plurality of service access units, each being coupled to the service exchange platform via a modified ETHERNET protocol, wherein
said modified ETHERNET protocol utilizes the MAC field to include ATM VPI/VCI type routing information.

2. The system according to claim 1, wherein:
said modified ETHERNET protocol includes a QOS identifier.

3. The system according to claim 2, wherein:
said QOS identifier is written in the MAC field.

4. The system according to claim 1, wherein:
said routing information is contained in one byte of the MAC field.

5. The system according to claim 3, eherein:
said QOS identifier is contained in the least significatnt byte of the MAC field.

6. The system according to claim 2, wherein:
said QOS identifier includes an indication of one of data, voice, and management.

7. A method of delivering multimedia communications services to multiple tenants in a building, said method comprising:
a) coupling a plurality of service access units to a service exchange platform;
b) encapsulating data in modified ETHERNET packets; and
c) transferring the modified ETHERNET packets between the service access units and the service exchange platform, wherein the modified ETHERNET packets include one of ATM VPI/VCI type routing information and a QOS identifier.

8. A method according to claim 7, wherein:
the QOS identifier is written in the MAC field.

9. A method according to claim 7, wherein:
the routing information is written in the MAC field.

10. A method according to claim 9, wherein:
said routing information is contained in one byte of the MAC field.

11. A method according to claim 8, eherein:
said QOS identifier is contained in the least significatnt byte of the MAC field.

12. A method according to claim 7, wherein:
said QOS identifier includes an indication of one of data, voice, and management.

13. A system for delivering multimedia communications services to multiple tenants in a building, said system comprising:
a a service exchange platform coupled to one or more private and/or public communications networks; and
b) a plurality of service access units, each being coupled to the service exchange platform via a modified ETHERNET protocol, wherein
said modified ETHERNET protocol includes a QOS identifier.

14. The system according to claim 13, wherein:
said QOS identifier is written in the MAC field.

15. The system according to claim 14, eherein:
said QOS identifier is contained in the least significatnt byte of the MAC field.

16. The system according to claim 13, wherein:
said QOS identifier includes an indication of one of data, voice, and management.

17. A method for transferring data between a network interface and a plurality of ports, said method comprising:
a) coupling the ports to the network interface via a bus;
b) encapsulating data in modified ETHERNET packets; and
c) transferring the modified ETHERNET packets over the bus, wherein
the modified ETHERNET packets include one of ATM VPI/VCI type routing information and a QOS identifier.

18. A method according to claim 17, wherein:
the QOS identifier is written in the MAC field.

19. A method according to claim 17, wherein:
the routing information is written in the MAC field.

20. A method according to claim 18, eherein:
the QOS identifier is contained in the least significatnt byte of the MAC field.

21. A method according to claim 18, wherein:
the QOS identifier includes an indication of one of data, voice, and management.

22. A system for transferring data, comprising:
a) a network interface;
b) a bus coupled to said network interface; and
c) a plurality of ports coupled to said bus, wherein data is transferred over the bus in modified ETHERNET packets,
the modified ETHERNET packets including one of ATM VPI/VCI type routing information and a QOS identifier.

23. A system according to claim 22, wherein:
the QOS identifier is written in the MAC field.

24. A system according to claim 22, wherein:
the routing information is written in the MAC field.

25. A system according to claim 23, eherein:
said QOS identifier is contained in the least significatnt byte of the MAC field.

26. A system according to claim 22, wherein:
said QOS identifier includes an indication of one of data, voice, and management.
